(19) United States
(12) Patent Application Publication
(10) Pub. No.: US 2026/0358404 A1
(43) Pub. Date: Nov. 12, 2026

(54) INTEGRATED CIRCUIT TEST STRUCTURE AND TEST METHOD THEREOF

(71) Applicant: TAIWAN SEMICONDUCTOR MANUFACTURING COMPANY, LTD., Hsinchu (TW)

(72) Inventors: Tse-Wei LIAO, Hsinchu (TW); Yang-Che CHEN, Hsinchu (TW); Chi-Hui LAI, Hsinchu (TW); Hsiang-Tai LU, Hsinchu (TW); Wei-Ray LIN, Hsinchu (TW)

(73) Assignee: TAIWAN SEMICONDUCTOR MANUFACTURING COMPANY, LTD., Hsinchu (TW)

(21) Appl. No.: 19/201,202

(22) Filed: May 7, 2025

(51) Int. Cl. G01R 31/28

(52) U.S. Cl. CPC G01R 31/2843; G01R 31/2856; G01R 31/2874; G01R 31/2879

(57) ABSTRACT

An integrated circuit test structure includes a plurality of interlayer dielectric layers, a plurality of conductive pattern layers, a plurality of via structures and a thermal sensing line. The conductive pattern layers and the via structures are alternately stacked in the interlayer dielectric layers and electrically connected to each other to form an interconnection structure, and the interconnection structure is suitable for passing a test current to detect an electrical defect generated in at least one test node of the via structures during a manufacturing process. The thermal sensing line surrounds the interconnection structure, and the thermal sensing line corresponds to a position of the at least one test node to sense a temperature change of the at least one test node.

### BACKGROUND

With the development of semiconductor technology, the difficulty of semiconductor process integration has increased rapidly. Therefore, test structures play a very important role in monitoring, controlling and tracing the sources of defects in the manufacturing process. As semiconductor devices are shrinking in size, chip-like test structures are also being designed and manufactured. The size of the chip-like test structure needs to be consistent with the actual product, such as the length distribution of the wires, the total number of contacts/vias, the chip area, the density of the contact/via pattern, etc. Therefore, when the size of the chip increases or the defect density decreases, defect isolation will require more time and difficulty than before. Because of this pressure, it is particularly important to design a test key that can monitor the process and track and reduce defect sources and mechanisms in a timely manner.

A daisy-chain design connects metal wire and via structures together to form a resistance monitoring structure. However, resistance measuring monitoring structure using the daisy chain is not sensitive because its resistance value has no direct correlation with via strength, and there is a lack of specific index to monitor via strength. The quality of the via structure can only be seen after thermal treatment during assembly and reliability analysis (RA) testing, but it is too late to find out whether the via bond quality is good or bad, and it is hard to determine the via strength level.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 are respectively a top view and a cross-sectional view along line A-A of an integrated circuit test structure according to an embodiment of the present disclosure.

FIG. 3 is a schematic diagram illustrating a test current passing through an integrated circuit test structure according to an embodiment of the present disclosure.

FIG. 4 is a flow chart of an integrated circuit test method according to an embodiment of the present disclosure.

FIG. 5 is a schematic diagram showing various test current patterns and test results thereof according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Semiconductor testing is an important step in the semiconductor design, production, packaging and testing process. By testing the device under tests (DUTs), we can identify defects, verify whether the DUTs meet the design goals, and separate the DUTs into good and bad products. Semiconductor testing can ensure that produced integrated circuits meet the required yield and reduce cost waste, while providing effective test data to improve semiconductor design and its process.

The semiconductor testing phase includes not only finish test (FT) and reliability test, but also design verification and wafer-level probing test (WLCP) during the manufacturing process. The equipment required during the testing process includes sorting machines, probe machines, testing machines, optical microscopes, defect observation settings, etc., to correspond to different testing flows. Design verification mainly tests the functional design of chip-like samples. It is carried out before production and mainly tests whether the functions of the chip design can meet customer requirements. Only products that have passed design verification will enter mass production. The tester 30 controls the test equipments by executing a set of test program instructions, and generates test signals and test patterns for the device under tests (DUTs). The output generated by the DUTs is fed back into the instrument of the tester 30 to measure its parameters, and the measurement results are compared with the programmed values stored in the tester 30 to determine whether the DUT is good or bad.

Wafer-level probing test is performed directly on the wafer. The wafer is placed on the tester 30 and each die of the wafer can be conducted to the probes of a probe card, and the test results of each die are recorded. The probe card is one of the connection interfaces between the tester 30 and the die on the wafer, and its purpose is to connect the tester 30 and the DUTs. When the probes of the probe card touch the bonding pads of each die on the wafer, the tester 30 sends a start signal to start the test. After the tester 30 completes the test, the tester 30 records the test results. The final test is to test the semiconductor package device. The semiconductor package device is placed on the handler, and the tester 30 tests the semiconductor package device. Then the handler grabs the semiconductor package device and puts it in the corresponding area for classification based on the test results of the tester 30.

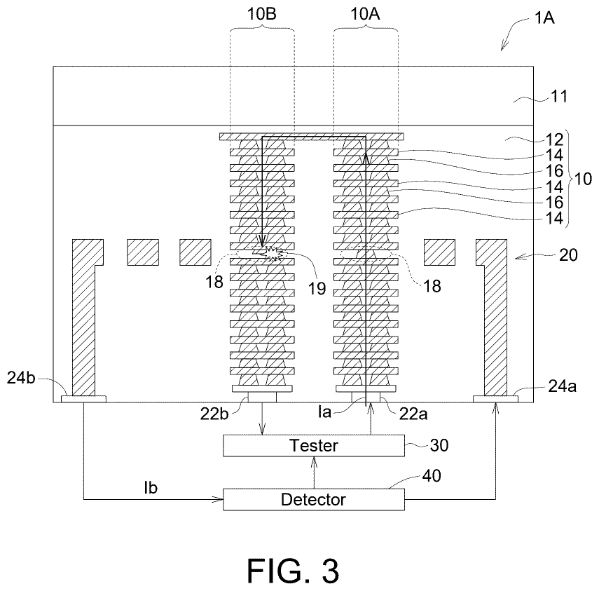

Semiconductor test items may include open circuit/short circuit test, DC test, function test, AC test, mixed signal test, RF test, etc. These tests can help to understand the fault types of the device under test and the adjustment strategies. Common electrical defects 19 (see FIG. 3) of the semiconductor dies may include bridge defects, open defects, and delay defects. These defects, alone or in combination, cause the circuit to behave unexpectedly, thus causing faults. Reliability faults generally do not manifest themselves until some extreme conditions, such as after thermal cycling or reliability testing of finished package products, but it is too late to find out the semiconductor die is not good. A bridging defect is caused by a short circuit between two or more nodes in a circuit. This bridging defect may be a short circuit at the node of a transistor or at the nodes of several transistors, which may be on the same layer on the die or on different layers of the die. Open defect is caused by improper manufacturing processes, and approximately 40% of physical defects are open defects. Typical open defects may include line disconnection, line thinning, resistive open circuit and gradual open circuit, among which via open fail (shown in FIG. 3) is a type of resistive open circuit or gradual open circuit. The form of the open defect depends on the location and size of the defect. When the defect area is small, current can still flow through the via structure 16, but the resistance of the interconnection structure 10 will increase. When the defect area is large, the current may not be able to pass through the via structure 16, resulting in an open circuit. In addition, the delay defect is caused, for example, by a small open circuit making the resistance of a certain line to be too large, and causing the signal delay time to exceed the interval of the clock.

In order to more effectively prevent reliability defects from occurring, various test methods must be provided to avoid wasting more die resources. The following embodiments and drawings illustrate the electrical defect 19 caused by via open fail, but the integrated circuit test structure 1A and the test method 1B disclosed herein are not limited to testing only open defects, and can also test other types of defects.

In some embodiments, the quality of the via structure 16 can be tested in a chip-like test structure with a tester 30 and a resistance/temperature detector 40 to detect via strength and screen out bad quality via structure 16 in stages prior to wafer accepted test (WAT), wafer probing test and final test.

Currently, there is no robust examination way to check via strength. Thus, a new via open test structure and a test method are proposed in the present disclosure to monitor via strength and the temperature measurement can be an index of a test current pattern input by tester 30. Also, bad quality via structure 16 with the open detects 19 can be screened out by changing test current pattern Ia in early stages. In this way, lots of cycle time and resource can be saved to improve the process to make via strength strong enough without the open detects 19.

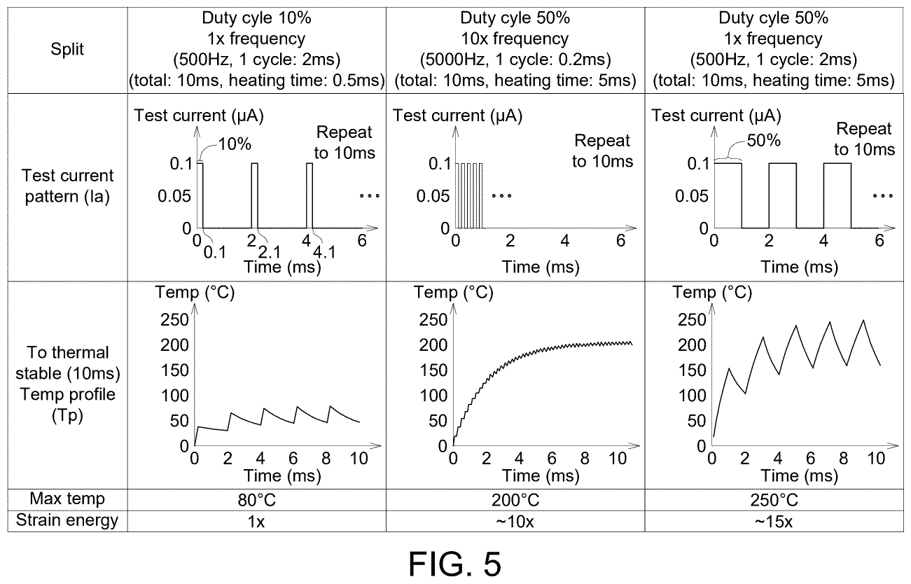

In some embodiments, via open test is adjustable by changing the test current pattern shown in FIG. 5. For example: a test current Ia is input by the tester 30, and the detector 40 shows 100 °C lower than the predetermined value, indicating that via structure 16 is strong enough to survive at 100 °C and pass the test, while the test current Ia can be changed and input by the tester 30. If the detector 40 shows 150 °C higher than the predetermined value, it means that the via structure 16 may open and the stress test of via structure 16 may fail. That is, the via structure 16 is not strong enough to survive at 150 °C, the temperature 150 °C of the test result can set as a pass index. According to the pass index, the semiconductor manufacturing process needs to improve to make via structure 16 strong enough to pass at 150 °C.

Also, in FIG. 5, the duty cycle of the test current can be adjusted to meet the required temperature of reliability test, which can evaluate reliability behavior of the via structure 16 in early stages without real reliability test environment to shorten process developing cycle time.

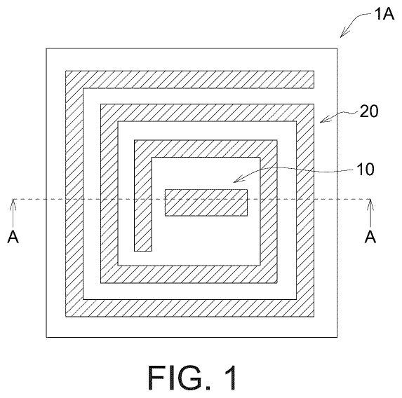

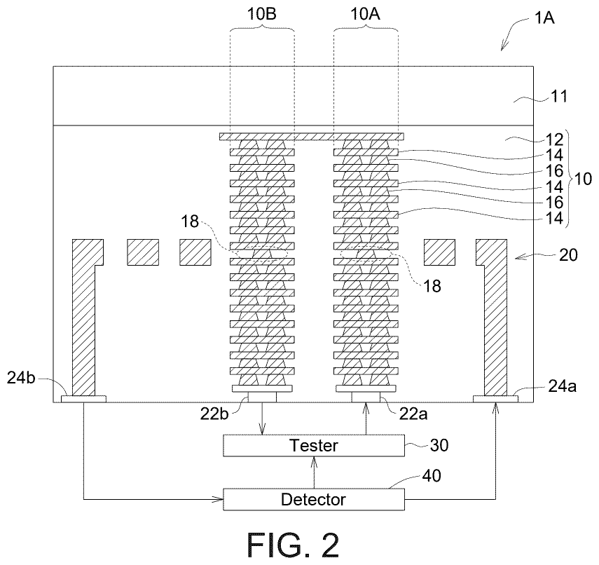

Referring to FIGS. 1 to 3. FIGS. 1 and 2 respectively illustrate a top view and a cross-sectional view along line A-A of an integrated circuit test structure 1A according to an embodiment of the present disclosure. FIG. 3 illustrates a schematic diagram of a test current Ia passing through the integrated circuit test structure 1A according to an embodiment of the present disclosure.

The integrated circuit test structure 1A may be a chip-like circuit, which includes a substrate 11, a plurality of interlayer dielectric layers 12, a plurality of conductive pattern layers 14, a plurality of via structures 16, and a thermal sensing line 20. The conductive pattern layers 14 and the via structures 16 are alternately stacked in the interlayer dielectric layers 12 and electrically connected to each other to form an interconnection structure 10.

Referring to FIGS. 1 and 2, the interconnection structure 10 is electrically connected to an external tester 30 through bonding pads 22a and 22b. The thermal sensing line 20 is electrically connected to an external resistance/temperature detector 40 through the bonding pads 24a and 24b. The tester 30 is used to input a test signal to the interconnection structure 10. In addition, the tester 30 is used to execute a set of test procedures to generate test signals and test patterns for the device under test (i.e., the interconnection structure 10), and receive output feedback signals generated by the device under test (i.e., the interconnection structure 10) to measure its electrical parameters. In addition, the resistance/temperature detector 40 is used to detect the resistance/temperature change of the thermal sensing line 20 and report the measurement result to the tester 30 to determine whether the device under test (i.e., the interconnection structure 10) has electrical defects or not.

In some embodiments, the substrate 11 includes various doped regions depending on circuit requirements (e.g., p-type semiconductor substrate or n-type semiconductor substrate). In some embodiments, the doped regions may be doped with p-type or n-type dopants. As illustrated in FIG. 1, the interconnection structure 10 is disposed on the substrate 11. The via structures 16 and the conductive pattern layers 14 are correspondingly embedded in one of the interlayer dielectric layers 12. On the other hand, the conductive pattern layers 14 located at different levels are electrically connected to one another through the via structures 16.

In some embodiments, a material of the interlayer dielectric layers 12 includes polyimide, epoxy resin, acrylic resin, phenol resin, benzocyclobutene (BCB), polybenzooxazole (PBO), or any other suitable polymer-based dielectric material. Alternatively, the interlayer dielectric layers 12 may be formed of oxides or nitrides, such as silicon oxide, silicon nitride, or the like. The interlayer dielectric layers 12 may be formed by suitable fabrication techniques such as spin-on coating, chemical vapor deposition (CVD), plasma-enhanced chemical vapor deposition (PECVD), or the like.

In some embodiments, a material of the conductive pattern layers 14 and the via structures 16 includes aluminum, titanium, copper, nickel, tungsten, or alloys thereof. The conductive pattern layers 14 and the via structures 16 may be formed by electroplating, deposition, and/or photolithography and etching. In some embodiments, the conductive pattern layers 14 and the underlying via structures 16 are formed simultaneously. It should be noted that the number of the interlayer dielectric layers 12, the number of the conductive pattern layers 14, and the number of the via structures 16 illustrated in FIG. 2 are merely for illustrative purposes, and the disclosure is not limited thereto.

Referring to FIGS. 1 and 2, the thermal sensing line 20 surrounds the interconnection structure 10, and the thermal sensing line 20 corresponds to the position of the at least one test node 18 in one of the via structures 16, for example, distributed in the same interlayer dielectric layer 12, to sense the temperature change around the test node 18. As shown in FIG. 3, the interconnection structure 10 is suitable for passing a test current Ia to detect an electrical defect generated in at least one test node 18 of one of the via structures 16 during the manufacturing process.

In some embodiments, the resistance of the thermal sensing line 20 increases as the temperature of the test node 18 rises. The temperature coefficient of resistance of the thermal sensing line 20 is between 100 and 3000 ppm/°C. The resistance of the thermal sensing line 20 complies with the following calculation formula: R=R₀[1+α(T−T₀)], where R is the final resistance, R₀ is the initial resistance, α is the temperature coefficient of resistance, T is the final temperature, and T₀ is the initial temperature. The material of the thermal sensing line 20 is copper, aluminum or a combination thereof, wherein the temperature coefficient of resistance of copper is about 3900 ppm/°C. The temperature coefficient of resistance, or TCR, is a measurement of a resistor's change in resistance per change in temperature. It is typically measured in ppm/°C, that is, parts-per-million change in ohms per change of 1 degree centigrade.

In some embodiments, the test node 18 may be located in any one of the plurality of interlayer dielectric layers 12. The number of the interlayer dielectric layers 12 is not limited, for example, between 3 and 20. The test node 18 may be located in the same interlayer dielectric layer 12 where the predetermined test node is located, and the test node 18 may be a single via structure 16, while other non-test nodes are double via structures 16, so that the resistance when the current passes through the test node 18 of single via structure is significantly greater than the resistance when the current passes through the double via structures 16.

The advantage of the single via structure 16 is that it can distinguish the non-test nodes of the double via structures 16, thereby simplifying the effect of the via strength when the current passes through the test node 18 on the electrical defect, thereby clearly determining whether the test node 18 has an open defect 19. As shown in FIG. 3, when an open defect 19 occurs at the test node 18, it means that the via strength of the test node 18 cannot withstand the stress change and thus an open defect 19 occurs. At the same time, the resistance of the test node 18 with the electrical defect 19 increases significantly when the current passing through the test node 18, thereby heat is generated in the test node 18, resulting in an increase in the temperature around the test node 18.

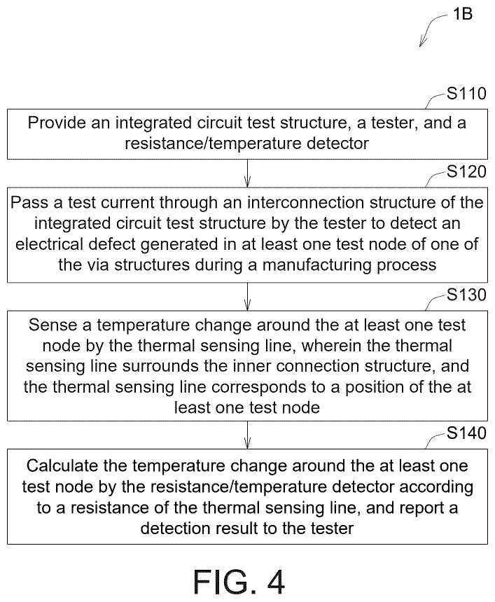

Referring to FIGS. 2 and 4, FIG. 4 is a flow chart of an integrated circuit testing method 1B according to an embodiment of the present disclosure. The integrated circuit testing method 1B is used to evaluate defects of contact/via window chains of an interconnection structure 10 of an integrated circuit, such as at least one of a bridge defect, an open defect, and a delay defect. The contact/via window chains may be formed by stacking multiple layers of contact patterns 14 and multiple layers of via structures 16, and may include a first contact/via window chain 10A and a second contact/via window chain 10B electrically connected to each other. An input end (bonding pad 22a) of the first contact/via window chain 10A is connected to the tester 30, and an output end (bonding pad 22b) of the second contact/via window chain 10B is connected to the tester 30 to form a test loop between the interconnection structure 10 and the tester 30. In addition, the thermal sensing line 20 and the test node 18 are configured to be distributed in the same interlayer dielectric layer 12. The thermal sensing line 20 can be a spiral line that surrounds the test node 18 from the inside to the outside. The resistance of the thermal sensing line 20 may change with temperature. The material of the thermal sensing line 20 may be copper, aluminum or other metals. The temperature coefficient of resistance of copper is approximately 3900 ppm/°C.

Referring to FIG. 4, the integrated circuit test method 1B may include the following steps S110-S140. In step S110, an integrated circuit test structure 1A, a tester 30 and a resistance/temperature detector 40 are provided. The integrated circuit test structure 1A is electrically connected to the tester 30, and the tester 30 is electrically connected to the resistance/temperature detector 40. In step S120, a test current Ia is supplied to the interconnection structure 10 by the tester 30 to detect an electrical defect 19 generated in at least one test node 18 of one of the via structures 16 during the manufacturing process. In step S130, the thermal sensing line 20 surrounds the interconnection structure 10, and the thermal sensing line 20 corresponds to the position of the at least one test node 18 of one of the via structures 16, for example, located in the same dielectric layer, so as to sense the temperature change around the test node 18. In step S140, the resistance/temperature detector 40 calculates the temperature change around the test node 18 according to the resistance value of the thermal sensing line 20, and reports the detection result to the tester 30.

In some embodiments, the current patterns, duty cycle and period time/frequency of the test current Ia can be changed according to actual test requirements. As shown in FIG. 5, the amplitude of the test current Ia may be 0.1 mA, the duty cycle thereof may be between 10% and 50%, the duration time of each cycle may be approximately between 0.2 ms and 2 ms, and the switching frequency may be approximately between 500 Hz and 5000 Hz. By detecting the temperature change around the test node 18, a temperature profile Tp can be obtained. Different test current patterns, duty cycles and duration time/frequencies generate corresponding temperature contours Tp to control the temperature around the test node 18 within a predetermined temperature range, such as controlling the temperature at approximately 80 degrees Celsius, 200 degrees Celsius, 250 degrees Celsius or other suitable temperatures. The proposed integrated circuit test structure is validated through electro-thermal-stress simulations. When a test current is input into the DUTs, the test current density at the via structure is relatively large, so that the temperature at the via structure is relatively high, resulting in relatively large strain energy at the via structure. In addition, lower frequencies and higher duty cycles will result in higher temperatures and strain energies (from 1× to 10× or 15×) to detect via strength and screen out via detects.

In step S130, the higher the temperature around the test node 18, the higher the current density input to the test node 18, and the greater the strain energy that the test node 18 needs to withstand. For example, in FIG. 5, when the temperature around the test node 18 is 80 degrees Celsius, the strain energy that the test node 18 needs to withstand is level one; when the temperature around the test node 18 is 200 degrees Celsius, the strain energy that the test node 18 needs to withstand is level ten; and when the temperature around the test node 18 is 250 degrees Celsius, the strain energy that the test node 18 needs to withstand is level fifteen, and so on. Therefore, in the embodiment of the present disclosure, whether the via strength of the test node 18 is strong enough to pass the test can be inferred based on the maximum temperature (max temp) that the test node 18 can withstand.

In step S140, the resistance/temperature detector 40 calculates the temperature change around the test node 18 according to the resistance value of the thermal sensing line 20. For example, the resistance/temperature detector 40 inputs a voltage signal to an input end (bonding pad 24a) of the thermal sensing line 20 and detects a current signal Ib at an output end (bonding pad 24b) of the thermal sensing line 20, and then obtains the resistance value of the thermal sensing line 20 according to Ohm's law. Since the resistance value of the thermal sensing line 20 is positively correlated with the temperature around the test node 18, the resistance of the thermal sensing line 20 increases by a predetermined proportion for each degree increase in the temperature of the thermal sensing line 20. Therefore, the resistance/temperature detector 40 can obtain the temperature change around the test node 18 by detecting the resistance value of the thermal sensing line 20.

In some embodiments, the resistance of the thermal sensing line 20 conforms to the following calculation formula: R=R₀[1+α(T−T₀)], where R is the final resistance, R₀ is the initial resistance, α is the temperature coefficient of resistance, T is the final temperature, and T₀ is the initial temperature. Since the temperature of the thermal sensing line 20 increases as the temperature of the test node 18 rises, the resistance value of the thermal sensing line 20 also increases. Therefore, the tester 30 can obtain the temperature around the test node 18 by sensing the resistance value of the thermal sensing line 20.

In step S140, the resistance/temperature detector 40 reports the resistance/temperature detection result to the tester 30. The tester 30 can determine whether the temperature around the test node 18 is abnormal based on the detection results. For example, the temperature of the test node 18 is higher than the reasonably expected temperature. The reason may be that the resistance of the test node 18 increases significantly when the test current Ia passes through the test node 18 with an electrical defect 19, thereby heat is generated in the test node 18, causing the temperature around the test node 18 to increase. Therefore, the tester 30 may determine that the test node 18 may have an electrical defect 19, such as an open defect, during the manufacturing process, and therefore cannot pass the test.

The present disclosure is related to an integrated circuit test structure and a test method thereof. In some embodiments, a test current is supplied to the interconnection structure by the tester to detect an electrical defect generated in at least one test node of one of the via structures during the manufacturing process. The thermal sensing line surrounds the interconnection structure, and the thermal sensing line corresponds to the position of the at least one test node of one of the via structures. The resistance/temperature detector calculates the temperature change around the test node according to the resistance value of the thermal sensing line, and reports the detection result to the tester. Therefore, it is determined that whether the temperature change around the test node is greater than an expected temperature to predict that the test node has an electrical defect. The higher the temperature, the greater the strain energy at the via structure. The greater the ability of the via structure to withstand strain energy, the greater the strength of the via structure. If the via structure is not strong enough, the higher strain energy will cause the via structure to fail as an open circuit.

According to some embodiments of the present disclosure, an integrated circuit test structure is provided, which includes a plurality of interlayer dielectric layers, a plurality of conductive pattern layers, a plurality of via structures and a thermal sensing line. The conductive pattern layers and the via structures are alternately stacked in the interlayer dielectric layers and electrically connected to each other to form an interconnection structure, and the interconnection structure is suitable for passing a test current to detect an electrical defect generated in at least one test node of the via structures during a manufacturing process. The thermal sensing line surrounds the interconnection structure, and the thermal sensing line corresponds to a position of the at least one test node to sense a temperature change of the at least one test node.

According to some embodiments of the present disclosure, a method for testing an integrated circuit is provided, which includes the following steps. An integrated circuit test structure, a tester and a resistance/temperature detector are provided, the integrated circuit test structure is electrically connected to the tester, the tester is electrically connected to the resistance/temperature detector, and the integrated circuit test structure includes an interconnection structure and a thermal sensing line. A test current is provided to pass through the interconnection structure by the tester to detect an electrical defect generated in at least one test node of one of the via structures during a manufacturing process. A temperature change around the test node is sensed by the thermal sensing line, the thermal sensing line surrounds the inner connection structure, and the thermal sensing line corresponds to a position of the at least one test node. The temperature change around the at least one test node is calculated by the resistance/temperature detector according to a resistance of the thermal sensing line, and a detection result is reported to the tester.

According to some embodiments of the present disclosure, a method for testing a tolerance strength of a test node is provided, which includes the following steps. A test current is provided to pass through the test node. A temperature change around the test node is calculated according to a resistance of a thermal sensing line surrounding the test node. It is determined that whether the temperature change around the test node is greater than an expected temperature to predict that the test node has an electrical defect.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit test structure, comprising:
a plurality of interlayer dielectric layers;
a plurality of conductive pattern layers;
a plurality of via structures; and
a thermal sensing line,
wherein the conductive pattern layers and the via structures are alternately stacked in the interlayer dielectric layers and electrically connected to each other to form an interconnection structure, and the interconnection structure is suitable for passing a test current to detect an electrical defect generated in at least one test node of the via structures during a manufacturing process,
wherein the thermal sensing line surrounds the interconnection structure, and the thermal sensing line corresponds to a position of the at least one test node to sense a temperature change of the at least one test node.

2. The integrated circuit test structure of claim 1, wherein a resistance of the thermal sensing line increases as a temperature of the at least one test node increases.

3. The integrated circuit test structure of claim 1, wherein the thermal sensing line and the at least one test node are configured to be distributed in a same one of the interlayer dielectric layers.

4. The integrated circuit test structure of claim 1, wherein the thermal sensing line is a spiral line.

5. The integrated circuit test structure of claim 1, wherein a material of the thermal sensing line is copper, aluminum or a combination thereof.

6. The integrated circuit test structure of claim 1, wherein the internal connection structure includes a first contact/via window chain and a second contact/via window chain electrically connected to each other, one end of the first contact/via window chain serves as an input end of the test current, and one end of the second contact/via window chain serves as an output end of the test current.

7. The integrated circuit test structure of claim 6, wherein the input end and the output end of the internal connection structure are connected to a tester to form a test loop.

8. The integrated circuit test structure of claim 1, wherein a duty cycle of the test current is between 10% and 50%, and a working switching frequency is between about 500 Hz and 5000 Hz.

9. The integrated circuit test structure of claim 1, wherein the electrical defect comprises an open defect.

10. A method for testing an integrated circuit, comprising:
providing an integrated circuit test structure, a tester and a resistance/temperature detector, wherein the integrated circuit test structure is electrically connected to the tester, the tester is electrically connected to the resistance/temperature detector, and the integrated circuit test structure includes an interconnection structure and a thermal sensing line,
passing a test current through the interconnection structure by the tester to detect an electrical defect generated in at least one test node of the interconnection structure during a manufacturing process;
sensing a temperature change around the test node by the thermal sensing line, wherein the thermal sensing line surrounds the interconnection structure, and the thermal sensing line corresponds to a position of the at least one test node; and
calculating the temperature change around the at least one test node by the resistance/temperature detector according to a resistance of the thermal sensing line, and reporting a detection result to the tester.

11. The method of claim 10, wherein the resistance of the thermal sensing line increases as a temperature of the at least one test node rises.

12. The method of claim 10, wherein the thermal sensing line and the at least one test node are configured to be distributed in a same one of a plurality of interlayer dielectric layers.

13. The method of claim 10, wherein the thermal sensing line is a spiral line.

14. The method of claim 10, wherein a material of the thermal sensing line is copper, aluminum or a combination thereof.

15. The method of claim 10, wherein the interconnection structure includes a first contact/via window chain and a second contact/via window chain electrically connected to each other, one end of the first contact/via window chain serves as an input end of the test current, and one end of the second contact/via window chain serves as an output end of the test current.

16. The method of claim 15, wherein the input end and the output end of the interconnection structure are connected to the tester to form a test loop.

17. The method of claim 10, wherein a duty cycle of the test current is between 10% and 50%, and a switching frequency of the test current is between 500 Hz and 5000 Hz.

18. The method of claim 10, wherein the electrical defect comprises an open defect.

19. A method for testing a tolerance strength of a test node, comprising:
providing a test current to pass through the test node;
calculating a temperature change around the test node according to a resistance of a thermal sensing line surrounding the test node; and
determining whether the temperature change around the test node is greater than an expected temperature to predict that the test node has an electrical defect.

20. The method of claim 19, wherein the resistance of the thermal sensing line is positively correlated with a temperature around the test node, and whether the tolerance strength of the test node is sufficient to pass a test is determined based on a maximum temperature that the test node withstand.
